(19) United States
(12) Patent Application Publication
(10) Pub. No.: US 2009/0165716 A1
(43) Pub. Date: Jul. 2, 2009

(54) Method and system for plasma enhanced chemical vapor deposition

(75) Inventor: Chun Wah FAN, Hong Kong (CN)

Correspondence Address: SILICON VALLEY PATENT AGENCY, 7394 WILDFLOWER WAY, CUPERTINO, CA, 95014, US

(73) Assignee: Dongguan Anwell Digital Machinery Ltd., Dongguang (CN)

(21) Appl. No.: 12/142,730

(22) Filed: Jun. 19, 2008

Related U.S. Application Data
(63) Continuation-in-part of application No. 11/968,188, filed on Jan. 1, 2008.

(51) Int. Cl. C23C 16/00

(52) U.S. Cl. 118/723 R

(57) ABSTRACT

Configurations for processing substrates are disclosed, where the substrates or workpieces may be used for manufacturing solar panels. According to one aspect of the present invention, a configuration includes a plurality of slender electrodes, and an injection panel including a plurality of holes. Each of the holes is provided to correspond to one of the slender electrodes with an opening. As a result, a type of chemical is injected through the opening when the electrode and a base are applied with a RF source.

### CROSS-REFERENCE TO RELATED APPLICATIONS

This application is a continuation-in-part of co-pending U.S. patent application Ser. No. 11/968,188, entitled “Method and system for handling objects in chambers”, filed on Jan. 1, 2008.

### BACKGROUND OF THE INVENTION

1. Field of the Invention

The invention is generally related to the area of manufacturing solar panels. More specially, the present invention is related to designs of chambers for processing substrates or workpieces and the method for doing the same.

2. Description of the Related Art

Plasma Enhanced Chemical Vapor Deposition (PECVD) is a process mainly to deposit thin films from a gas state (vapor) to a solid state on some substrate. There are some chemical reactions involved in the process which occur after creation of a plasma of the reacting gases. The plasma is generally created by RF (AC) frequency or DC discharge between two electrodes, the space between which is filled with the reacting gases.

PECVD uses electrical energy to generate a glow discharge (plasma) in which the energy is transferred into a gas mixture. This transforms the gas mixture into reactive radicals, ions, neutral atoms and molecules, and other highly excited species. These atomic and molecular fragments interact with a substrate and, depending on the nature of these interactions, either etching or deposition processes occur at the substrate. These energized fragments, however, may cause a certain level of damage to a film that is being or already deposited on the substrate.

Thus, there is a demand for better PECVD processes. The present invention discloses techniques for processing substrates in a chamber. Although the substrates are suitable for manufacturing the solar panels, those skilled in the art may appreciate that the techniques herein are equally suitable for other parts or applications.

### SUMMARY OF THE INVENTION

This section is for the purpose of summarizing some aspects of the present invention and to briefly introduce some preferred embodiments. Simplifications or omissions in this section as well as in the abstract or the title of this description may be made to avoid obscuring the purpose of this section, the abstract and the title. Such simplifications or omissions are not intended to limit the scope of the present invention.

In general, the present invention pertains to mechanism for processing substrates, where the substrates or workpieces may be used for manufacturing solar panels. According to one aspect of the present invention, a configuration includes a plurality of slender electrodes and an injection panel including a plurality of holes. Each of the holes is provided to accommodate one of the slender electrodes with a ring like space as an opening surrounding one of the slender electrodes. As a result, a type of chemical is injected through the opening and discharges when the electrode are applied with a RF source.

Depending on implementation and the character of the chemical, the slender electrodes may be designed differently in a shape corresponding to the shape of the holes of the injection panel to maximize the discharging efficiency.

The present invention may be implemented as a method, an apparatus, a system or a part of system. According to one embodiment, the present invention is a system for processing workpieces, the system comprises: a planer electrode including a plurality of slender structures; a base being heated by a heater or a heater; an injection panel including a plurality holes, each of the holes accommodating one of the slender electrodes with a ring like space as an opening surrounding the one of the slender electrodes, wherein a type of chemical is injected through the opening into a vacuum in which a substrate is disposed therein for being treated with the chemical when an electronic source is applied across the slender electrode and the injection panel.

The present invention may be used in a number of applications, such as plasma enhanced chemical vapor deposition (PECVD) that is a process mainly to deposit thin films from a gas state (vapor) to a solid state on a substrate. Other objects, features, and advantages of the present invention will become apparent upon examining the following detailed description of an embodiment thereof, taken in conjunction with the attached drawings.

### BRIEF DESCRIPTION OF THE DRAWINGS

These and other features, aspects, and advantages of the present invention will become better understood with regard to the following description, appended claims, and accompanying drawings where:

FIG. 1 shows an exemplary configuration 100 according to one embodiment of the present invention;

FIG. 2 shows a surface view of an injection panel that may be used in FIG. 1;

FIG. 3 shows a front view of a configuration of an electrode and a corresponding injection panel;

FIG. 4A-FIG. 4C shows respective cross-section views of three different configurations of an electrode and a corresponding injection panel;

FIG. 5 shows a cross-section view of another exemplary configuration of an electrode and a corresponding injection panel;

FIG. 6 shows a configuration in which two substrates being treated are separated by a base; and

FIG. 7 shows a configuration in which two substrates being treated are separated by a space.

### DETAILED DESCRIPTION OF THE PREFERRED EMBODIMENTS

The detailed description of the present invention is presented largely in terms of procedures, steps, logic blocks, processing, or other symbolic representations that directly or indirectly resemble the handling of workpieces in a system. These descriptions and representations are typically used by those skilled in the art to most effectively convey the substance of their work to others skilled in the art.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments mutually exclusive of other embodiments. Further, the order of blocks in process flowcharts or diagrams or the use of sequence numbers representing one or more embodiments of the invention do not inherently indicate any particular order nor imply any limitations in the invention.

Embodiments of the present invention are discussed herein with reference to FIGS. 1-7. However, those skilled in the art will readily appreciate that the detailed description given herein with respect to these figures is for explanatory purposes as the invention extends beyond these limited embodiments.

Referring now to the drawings, in which like numerals refer to like parts throughout the several views. FIG. 1 shows an exemplary configuration 100 according to one embodiment of the present invention. The configuration 100 is shown as a portion of a cross-section of a chamber in which one or more substrates are being processed. The configuration 100 includes an array of slender electrodes 103, injection panels 104, and a base 106 that is typically a heater or a base heated by a heater. The slender electrodes are mounted on a mounting plate 102. From a cross-section perspective, the slender electrodes 103 are accommodated in the holes on the injection panel 104. A ring shaped space 112 is kept therebetween a slender electrode and a hole. A space 110 is also kept between the mounting plate 102 and the injection panel 104. As a result, a conduit or some room 110 is formed between the mounting plate 102 and the injection panels 104, where a type of gas is supplied thereto. Under a certain pressure, the gas is injected though openings 112 provided by the spaces between each of the columns and the injection panel 104.

In operation of processing a substrate 108, the slender electrodes 103 are applied with an electronic source (e.g., RF source) and the injection panel 104 is applied with ground potential. As a result, electrical energy from the RF source creates an electric field that generates a glow discharge (plasma) in which the energy is transferred into a gas mixture. This discharging process transforms the gas into reactive radicals, ions, neutral atoms and molecules, and other highly excited species, collectively referred to as excited particles. Because the openings 112 formed by the slender electrode 103 and the injection panels 104 are small, these excited particles are injected into the chamber and subsequently interacts with the substrate 108.

Physically, the distance between the slender electrode 103 and the substrate 108 is relatively larger than that between the electrode 103 and the injection panels 104. Thus the electric field becomes relatively weaker near the substrate 108 than that near the injection panels 104, thus the excited particles would have less dynamic energy against or impact on the substrate 108 when they reach or interact with the substrate 108.

According to another embodiment, an additional voltage bias may be applied to the base 106 to further weaken the excited particles to a certain level before they reach the surface of the substrate 108, thus reducing effectively possible damage to a thin film being formed or already formed on the substrate 108.

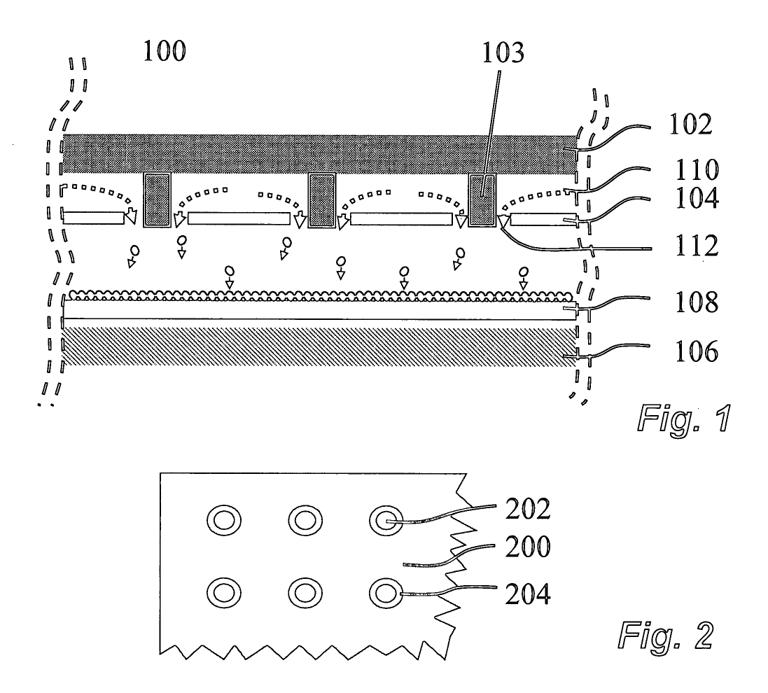

FIG. 2 shows a surface view of an injection panel 200 that may be used in FIG. 1. The injection panel 200 includes a plurality of holes, each of the holes to accommodate a column 202 (of the electrode 103). The size of each of a hole is slightly larger than that of the column 202, thus creating a ring-like opening 204 through which the excited gas is injected through.

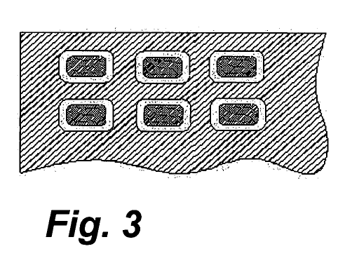

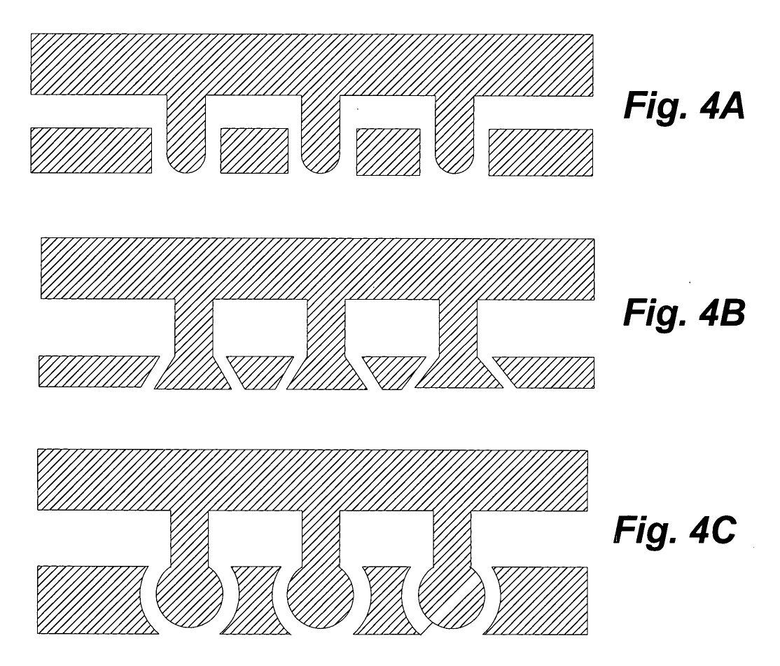

FIG. 3 shows an exemplary implementation of the slender electrode wherein the electrode is designed as a rectangular stud. FIG. 4A-FIG. 4C shows respective cross-section views of three different configurations of an electrode and a corresponding injection panel. FIG. 4A shows one design in which the studs of the electrode are designed to have rounding ends to have a uniform distributed discharging, or at least to avoid sharp discharging from angled or acute ends of the studs. FIG. 4B shows another design in which the studs of the electrode are designed to have a shape of reversed triangle. One of the features having the studs of the electrode shaped reversed triangle is to increase the discharging areas. Similarly, FIG. 4C shows still another design in which the studs of the electrode are made of round shape to increase the discharging areas.

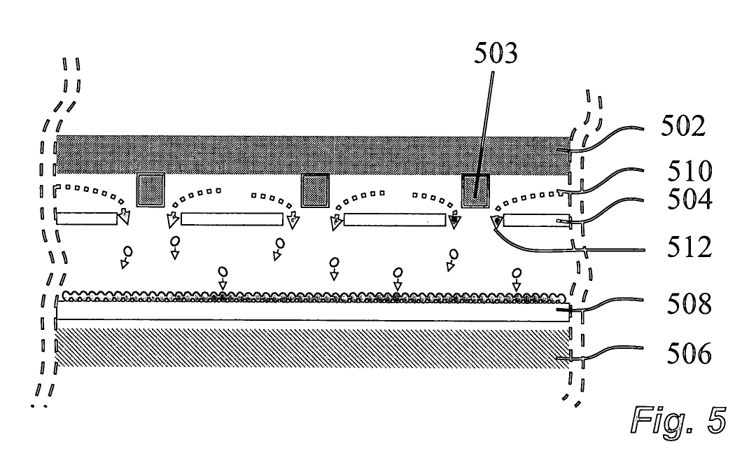

FIG. 5 shows another exemplary embodiment of the slender electrode 503. The electrodes 503 are aligned with the holes on the injection panel 504 with some retraction from the injection panel 504 thereby further reducing the electromagnetic field between the electrode and the workpiece being processed.

As far as the dimension of the studs of the electrode or the openings is concerned, it largely depends on the machining accuracy, a predefined gas flow rate, and the uniformity of a film to be deposited as well as the dimension of the substrate. In operation, a type of chemical (e.g., gas) is fed into the space between the electrode and the injection panel. Under an electric field generated between the slender structures of the electrode and the injection panel, the chemical is injected through the openings into a vacuum where there is a substrate being processed (e.g., a film is being deposited thereupon). An outlet may be provided to release the residual or leftover of the chemical and to balance the pressure in the vacuum (the chamber).

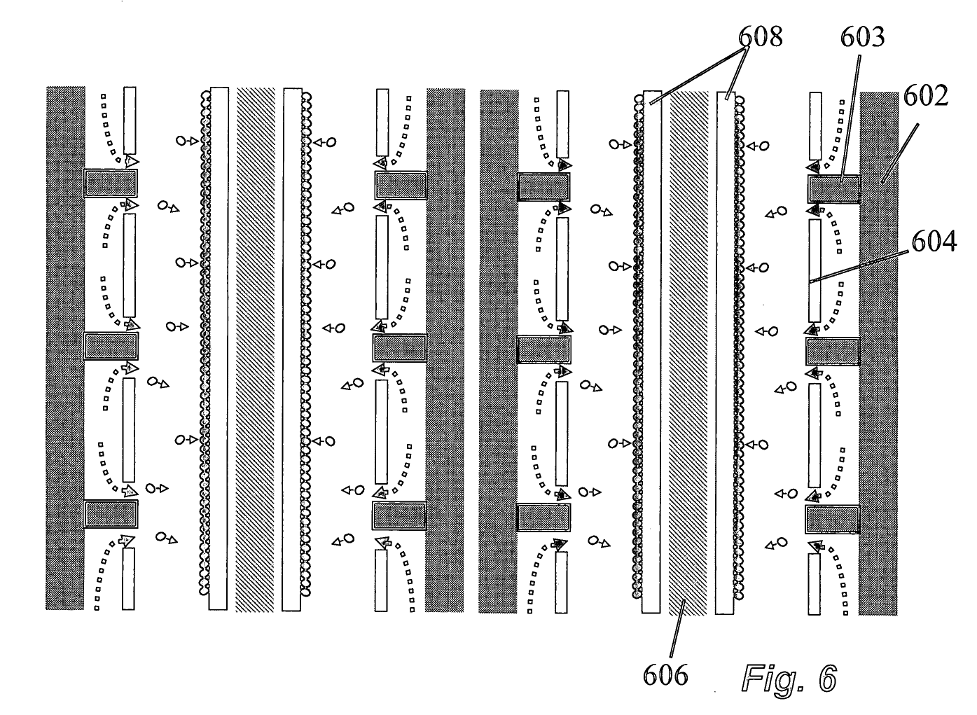

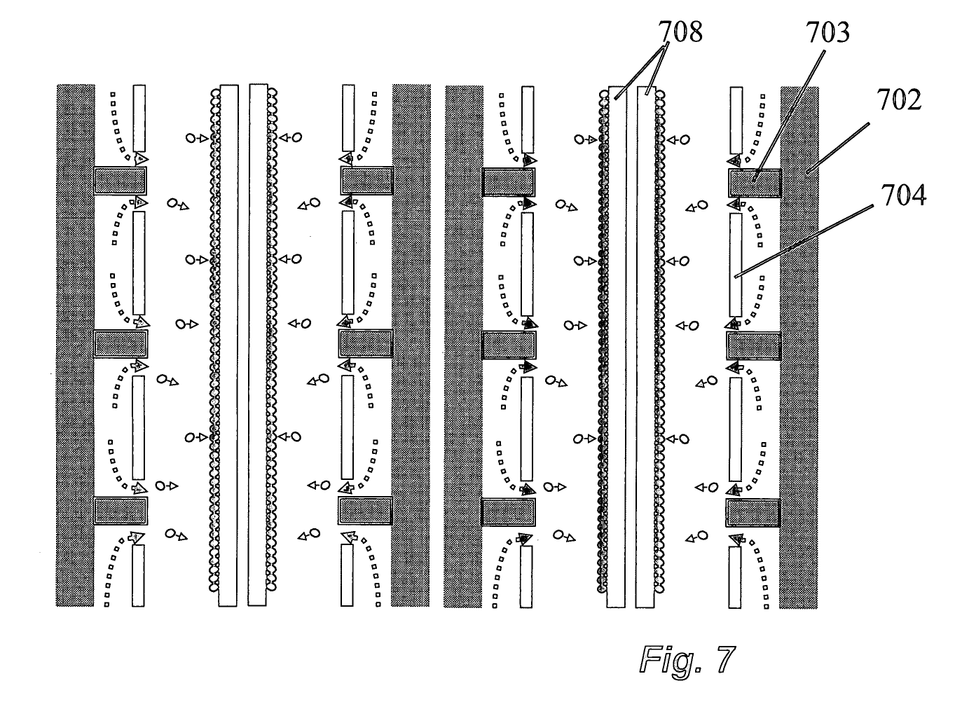

FIG. 6 shows a configuration in which a pair of substrates 608 being treated is separated by a base 608. The configuration shoes that the base 608 (e.g., it is heated) may be efficiently used to simultaneously support or heat two substrates at the same time. However, in a situation in which there is no need for a base, FIG. 7 shows that two substrates 708 are positioned back to back.

One of the objects, advantages and benefits in the present invention is to weaken the excited particles before they reach the substrate by having a relatively long distance between the substrate and the electrode than the distance between the electrode and the injection panel. To further weaken the excited particles to a predefined level, an additional voltage bias may be applied to a base. Various designs of the slender structures are also proposed to fit a specific application as well as a typical chemical being used.

The above description discloses a system configuration for processing workpieces or depositing one or more types of chemical thereon. The invention may be used in many applications, such as treating workpieces with chemical components. For example, one embodiment of the present invention can be advantageously used in chemical vapor deposition (CVD) in which electric power is not applied to the deposition assembly or deposition assembly is omitted.

The present invention has been described in sufficient details with a certain degree of particularity. It is understood to those skilled in the art that the present disclosure of embodiments has been made by way of examples only and that numerous changes in the arrangement and combination of parts may be resorted without departing from the spirit and scope of the invention as claimed. Accordingly, the scope of the present invention is defined by the appended claims rather than the foregoing description of embodiments.

I claim:

1. A system for processing workpieces, the system comprising:
a plurality of slender electrodes;
an injection panel including a plurality holes, each of the holes accommodating one of the slender structures with a ring like space as an opening surrounding the one of the slender structures, wherein a type of chemical is injected through the opening into a vacuum in which a substrate is disposed therein for being treated with the chemical when an electronic source is applied across the slender structures and the injection panel.

2. The system as recited in claim 1, further including a base being heated by a heater or a heater.

3. The system as recited in claim 2, wherein an additional voltage bias is applied to the base.

4. The system as recited in claim 1, wherein the slender electrodes are designed to have rounding ends to have a uniform distributed discharging, or at least to avoid sharp discharging from angled or acute ends of the slender structures.

5. The system as recited in claim 1, wherein the slender electrodes are designed to have a shape of reversed triangle to increase discharging areas.

6. The system as recited in claim 1, wherein the slender electrodes are made of round shape to increase discharging areas.

7. The system as recited in claim 1, wherein each of the slender electrodes is designed as a cylindrical stud.

8. The system as recited in claim 1, wherein each of the slender electrodes is designed as a rectangular stud.

9. The system as recited in claim 2, wherein the slender electrodes are designed to have rounding ends to have a uniform distributed discharging, or at least to avoid sharp discharging from angled or acute ends of the slender structures.

10. The system as recited in claim 2, wherein the slender electrodes are designed to have a shape of reversed triangle to increase discharging areas.

11. The system as recited in claim 2, wherein the slender electrodes are made of round shape to increase discharging areas.

12. The system as recited in claim 3, wherein the slender electrodes are designed to have rounding ends to have a uniform distributed discharging, or at least to avoid sharp discharging from angled or acute ends of the slender structures.

13. The system as recited in claim 3, wherein the slender structures of the electrodes are designed to have a shape of reversed triangle to increase discharging areas.

14. The system as recited in claim 3, wherein the slender structures of the electrodes are made of round shape to increase discharging areas.

15. A system for processing workpieces, the system comprising:
a plurality of slender electrodes,
an injection panel including a plurality holes, the slender electrodes being aligned and retracted from the holes on the injection panel, wherein a type of chemical is injected through the opening into a vacuum in which a substrate is disposed therein for being treated with the chemical when an electronic source is applied across the electrode and the injection panel;

16. The system as recited in claim 15, further including a base being heated by a heater or a heater.

17. The system as recited in claim 16, further including a means for applying an additional voltage bias to the base.

18. The system as recited in claim 15, wherein the slender electrodes are designed to have rounding ends to have a uniform distributed discharging, or at least to avoid sharp discharging from angled or acute ends of the slender structures.

19. The system as recited in claim 16, wherein the slender electrodes are designed to have rounding ends to have a uniform distributed discharging, or at least to avoid sharp discharging from angled or acute ends of the slender structures.

20. The system as recited in claim 17, wherein the slender electrodes are designed to have rounding ends to have a uniform distributed discharging, or at least to avoid sharp discharging from angled or acute ends of the slender structures.
